(19) United States
(12) Patent Application Publication
(10) Pub. No.: US 2026/0255685 A1
(43) Pub. Date: Aug. 27, 2026

(54) INTEGRATED CIRCUIT HAVING FDSOI-TYPE FIELD-EFFECT TRANSISTOR MATCHING

(71) Applicant: STMicroelectronics International N.V., Geneva (CH)

(72) Inventor: Gilles Chevalier-Charrin, Saint Etienne De Sai (FR)

(21) Appl. No.: 19/544,265

(22) Filed: Feb. 19, 2026

(30) Foreign Application Priority Data
Feb. 21, 2025 (FR) FR2501794

(51) Int. Cl. H10D 89/10; G05F 3/26; H10D 86/00

(52) U.S. Cl. CPC H10D 89/10; G05F 3/262; H10D 86/201

(57) ABSTRACT

The present description is directed to an integrated circuit, including an FDSOI substrate where the top thin layer of silicon has a non-zero periodic variation in wavelength thickness λ_{TSi}. It includes an assembly of so-called main FDSOI type field effect transistors. Each main transistor is segmented into several elementary transistors having width We and length Le less than or equal to λ_{TSi}/2. The elementary transistors of a same main transistor are separated two by two by a distance greater than λ_{TSi}/2. The elementary transistors, adjacent by their sides, belong two by two to different main transistors, and are separated from each other by a distance less than or equal to λ_{TSi}/2.

### CROSS-REFERENCE TO RELATED APPLICATIONS

This application claims the benefit of French Patent Application No. 2501794, filed on February 21, 2025, which application is hereby incorporated herein by reference.

### TECHNICAL FIELD

This description generally relates to integrated circuits including field effect transistors of the FDSOI (Fully Depleted Semiconductor On Insulator) type.

### BACKGROUND

Integrated circuits may include assemblies of field effect transistors having as identical electrical characteristics as possible. This is particularly the case with current mirror or differential pair assemblies, commonly used in analogue circuits.

The current mirror may include for example a reference transistor, assembled as a diode, and one or more copy transistors. The transistors are coupled with common gate and common source. The current mirror makes it possible to duplicate the current flowing in the reference branch in each of the copy branches.

A differential pair may be formed of two transistors coupled with common source and biased to a current source. It makes it possible to amplify, with a high gain, a potential difference between gate voltages of the two transistors.

In both cases, the performance of the circuit depends on matching of the transistors, i.e., whether or not the electrical characteristics of the transistors are identical. Thus, the transistors are said to be matched when they have identical electrical characteristics. The circuit then has the expected performance.

However, a mismatch may result from the presence of overall variations at the wafer or chip scale during the steps of the manufacturing method. These may be gradient phenomena (e.g. temperature or doping), which form systematic overall variations. These may also be local variations or fluctuations, with a random nature.

Especially, to limit amplitude of the overall fluctuations, the transistors are made simultaneously, from a same wafer, and are disposed as close as possible to each other. Moreover, each transistor may also be segmented into several transistors of small sizes and connected in parallel and/or in series, which may especially help to limit the impact of local fluctuations. The matched and segmented transistors can then be positioned interdigitated and with a common centroid). This is called Pelgrom matching, with reference to the publication of Pelgrom et al. entitled Matching Properties of MOS Transistors, IEEE J. Solid-State Circuits, Vol.24, p.1433-1440, 1989.

Furthermore, the transistors may be of the FDSOI type. FDSOI transistors then include a top thin layer of totally depleted single crystal silicon (TSi, for Top Silicon), formed on a Buried OXide (BOX), where the channel regions are located. It is possible to modulate the threshold voltage efficiently by biasing the back gate.

However, as indicated in document FR 3,057,104 A1, the top TSi thin layer may have a thickness uniformity defect from one transistor to the other, which may impact electrical characteristics of the transistors, in particular their threshold voltage, and therefore degrade matching.

There is also a need to have an integrated circuit including FDSOI type field effect transistors having an improved matching.

### SUMMARY

According to one aspect of the present disclosure, there is provided an integrated circuit including an assembly of FDSOI type field effect transistors, remedying all or part of the above-mentioned drawbacks.

For this, the integrated circuit includes:

an FDSOI substrate, including a top thin layer of silicon covering an insulating layer, the top thin layer having a non-zero periodic variation in wavelength thickness λ_{TSi};

at least one assembly of so-called main FDSOI type field effect transistors, formed in and on the FDSOI substrate;

each main transistor being segmented into several elementary transistors having width We and length Le less than or equal to λ_{TSi}/2;

the elementary transistors of a same main transistor being spaced two by two by a distance greater than λ_{TSi}/2;

the elementary transistors, adjacent by their sides, belonging two by two to different main transistors, and being distant from each other by a distance less than or equal to λ_{TSi}/2.

The wavelength λ_{TSi} may be equal to 2.3µm, to the nearest 10%.

Each elementary transistor may have the same dimensions We, Le.

The width We and the length Le can be equal.

The width We and the length Le of the elementary transistors may be equal to 1µm, to the nearest 10%.

Elementary transistors can be aligned in rows and columns.

Each row and each column may include elementary transistors of at most four different main transistors.

The assembly may comprise at most nine main transistors.

Elementary transistors adjacent by their vertices can belong two by two to identical or different main transistors.

Elementary transistors may be arranged in rows and columns by repeating a unit pattern.

The transistor assembly may be a current mirror formed of a diode-assembled main transistor and of at least one main copy transistor.

The unit pattern may include at least one elementary transistor of the diode-assembled main transistor, and at least one elementary transistor of each main copy transistor.

Each elementary transistor of a copy transistor may include a side or a vertex adjacent, respectively, to a side or a vertex of an elementary transistor of the diode-assembled main transistor.

According to another aspect, there is provided an electronic chip including an integrated circuit according to any of the preceding characteristics.

### BRIEF DESCRIPTION OF THE DRAWINGS

Further advantages and characteristics of the invention will become apparent upon examining the detailed description of non-limiting embodiments and implementations, and from the appended drawings wherein:

FIG. 1 is a schematic and partial cross-sectional view of FDSOI-type field effect transistors;

FIG. 2A illustrates an example assembly of current mirror transistors;

FIG. 2B illustrates the segmentation of a main transistor into an equivalent assembly of several elementary transistors of small dimensions;

FIG. 2C illustrates a main transistor segmented into elementary transistors;

FIG. 3A illustrates an integrated circuit including a current-mirror transistor assembly;

FIG. 3B illustrates an integrated circuit according to one embodiment, including an assembly of elementary transistors equivalent to that of FIG. 3A;

FIG. 4A illustrates a unit pattern of elementary transistors of a current mirror with one copy transistor;

FIG. 4B illustrates an integrated circuit according to one embodiment, including a current mirror assembly formed of the unit pattern of FIG. 4A repeated several times;

FIG. 5A illustrates a unit pattern of elementary transistors of a current mirror to two copy transistors;

FIG. 5B illustrates an integrated circuit according to one embodiment, including a current mirror assembly formed of the unit pattern of FIG. 5A repeated several times;

FIG. 6A, FIG. 6B, FIG. 6C, FIG. 6D, FIG. 6E, FIG. 6F illustrate integrated circuits according to different embodiments, each including a current mirror transistor assembly having three to eight copy transistors, the assembly being formed of a unit pattern of elementary transistors repeated several times;

FIG. 7A illustrates an example assembly of elementary transistors equivalent to a main transistor;

FIG. 7B illustrates an integrated circuit according to one embodiment, including a current mirror assembly formed of several unit patterns;

FIG. 7C illustrates part of the integrated circuit of FIG. 7B, with the conductive lines for electrical connection of the elementary transistors.

### DETAILED DESCRIPTION OF ILLUSTRATIVE EMBODIMENTS

In the figures and in the following description, the same references represent identical or similar elements. In addition, the different elements are not represented to scale in such a way as to favor clarity of the figures. Furthermore, the different embodiments and alternatives are not exclusive of each other and may be combined together.

Unless otherwise indicated, the terms “substantially”, “about”, “in the order of” mean to the nearest 10%, and preferably to the nearest 5%. Furthermore, the terms “between … and …” and equivalents mean that bounds are included, unless otherwise stated.

Furthermore, the terms “coupled” and “connected” refer to two elements coupled or connected to each other either directly or indirectly through one or more intermediate elements. On the other hand, the terms “directly coupled” and “directly connected” mean that the two elements are coupled or connected without any other intermediate element.

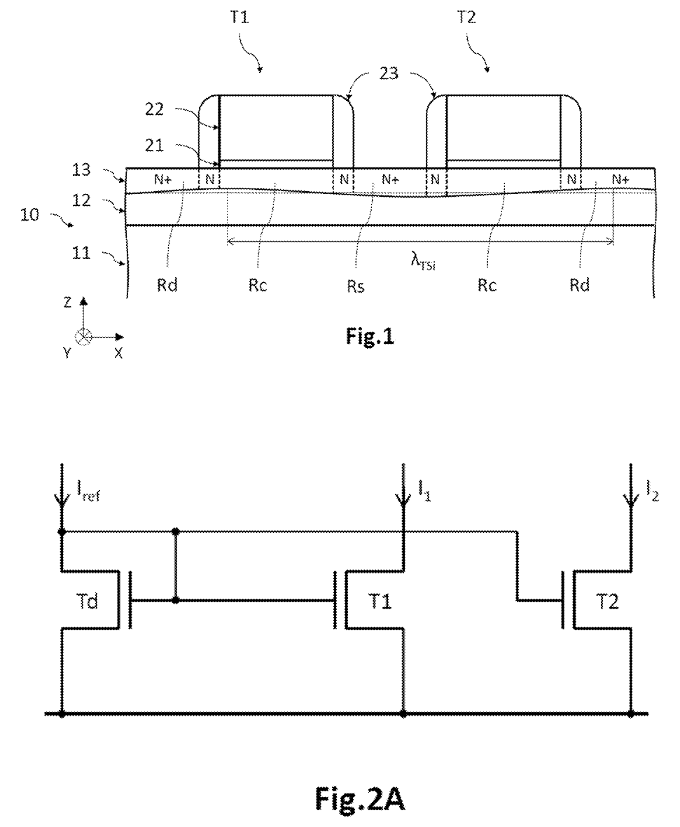

FIG. 1 is a schematic and partial transverse cross-section view of FDSOI type field effect transistors, noted T1 and T2.

Herein and for the remainder of the description, a three-dimensional direct system XYZ is defined, in which the plane XY is parallel to the plane in which the substrate FDSOI 10 extends in and on which the transistors T1, T2 are made, and in which the axis Z is oriented along the thickness thereof. Furthermore, the terms “lower” and “upper” are understood to be relative to an increasing positioning along the direction +Z.

The transistors T1, T2 are made in and on a top thin layer 13 of single crystal silicon, referred to as the TSi layer. The latter rests on a layer 12 of buried oxide covering a thick layer 11 of silicon.

Each transistor T1, T2 includes a channel region Rc located between a source region Rs and a drain region Rd. The channel region Rc is located under a gate 22 and isolated therefrom by an insulating portion 21. The lateral flanks of the gate 22 are covered with spacers 23. The source regions Rs and drain regions Rd extend under the spacers as less doped zones.

Here, the transistors T1, T2 are with N-type channel. Hence, the source regions Rs and drain regions Rd are here strongly N+ doped and the less doped zones are N doped.

In this example, the transistors T1, T2 are coupled together to form for example a current mirror. The source region Rs is common to the transistors T1 and T2, and is connected to a ground GND. The gates 22 are connected to the same electrical potential.

The Applicant has found that the thickness of the TSi thin layer 13 has substantially periodic variations, in the plane XY, of non-zero spatial wavelength λ_{TSi}, of the order of a few microns. More precisely, the wavelength λ_{TSi} has been measured at about 2.3µm (to the nearest 10% or even to the nearest 5%).

The thickness of the TSi thin layer 13 is defined as the distance along the axis Z between the upper face of the single crystal silicon of the layer 13 and its lower opposite face in contact with the buried oxide.

In the figure, the upper face is substantially planar while its lower face has a topological variation. However, the upper face may also have a topological variation. The amplitude of this periodic variation may, by way of example, be in the order of 1nm for an average thickness of the TSi thin layer 13 in the order of a few nanometers, for example 6nm.

For example, the spatial wavelength λ_{TSi} may be determined from atomic force microscope measurements followed by a spectral analysis, especially using a power spectral density function.

It is understood that this periodic variation in thickness of the TSi thin layer 13 is distinguished from the roughness of a silicon layer, this roughness having much smaller spatial scales, for example in the order of one nanometer or ten nanometers.

This periodic variation in thickness of the TSi thin layer can lead to a degradation of matching of the FDSOI transistors supposed to be identical in terms of electrical characteristics, in particular when the FDSOI transistors are each segmented into a plurality of so-called elementary transistors of small dimensions.

Let us consider an example of current mirror transistor assembly, where each so-called main transistor is segmented into so-called elementary transistors of smaller dimensions.

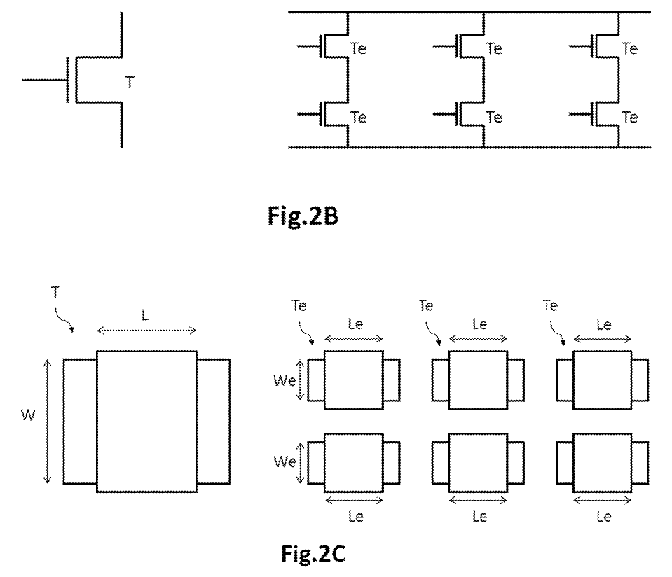

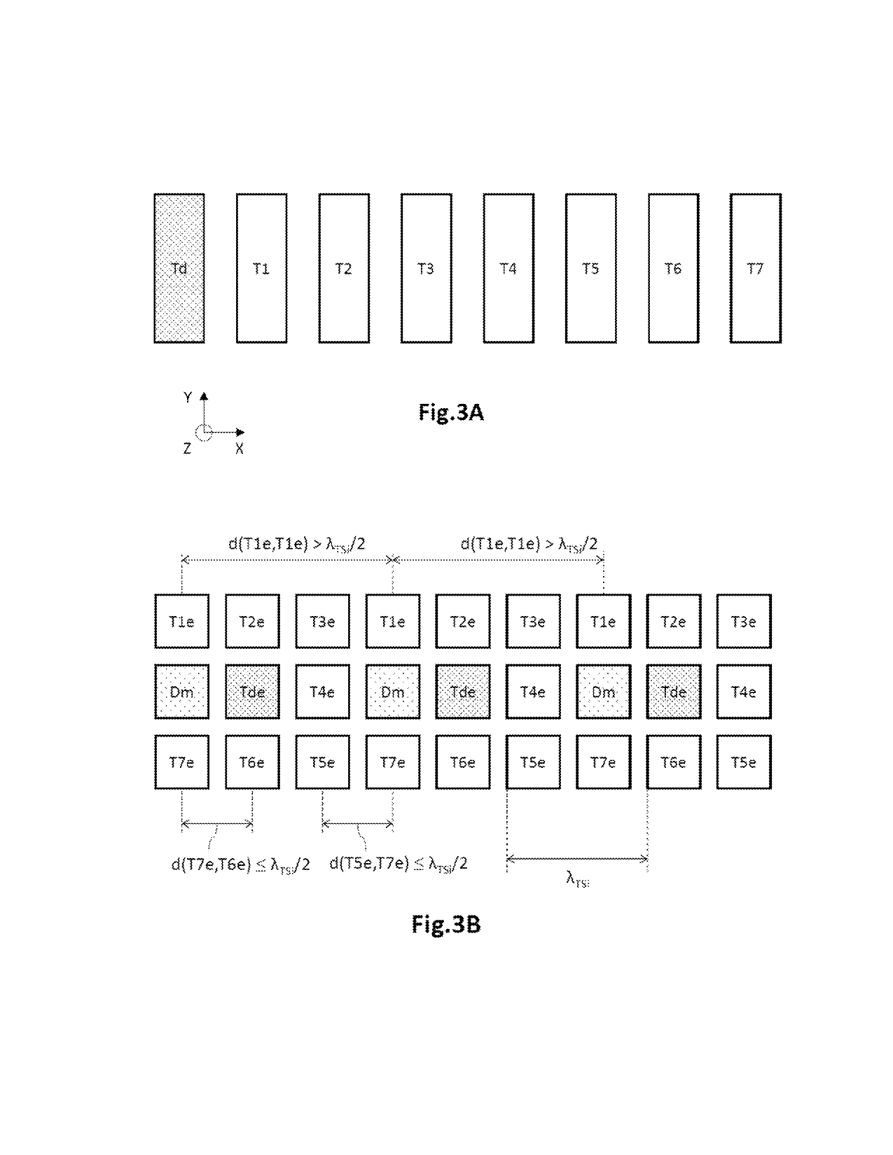

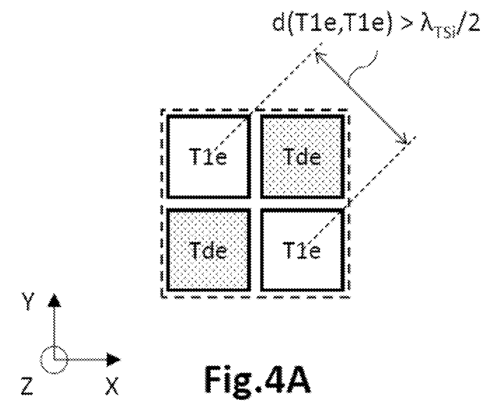

In this respect, FIG. 2A illustrates an example assembly of current mirror transistors. In this example, the current mirror assembly includes a reference branch with a diode-assembled transistor Td, and several copy branches, here two branches, each comprising a transistor T1 or T2. The main transistors Td, T1, T2 are coupled with common gate and with common source. In this assembly, the current mirror provides two copies I1 and I2 of the reference current Iref.

FIG. 2B illustrates an example segmentation of a main transistor having dimensions W, L into several elementary transistors of smaller dimensions We, Le, connected in parallel and/or in series. FIG. 2C schematically illustrates the main transistor and the elementary transistors of FIG. 2B. The width W, We is the width of the active zone of the transistor, and the length L, Le is the length of the channel region located under the gate.

In this example, the main transistor T has a width W equal to 3µm and a length L equal to 2µm. This main transistor T is then equivalent to a matrix of dimensions N ×M (N rows and M columns) of elementary transistors Te of spatial dimensions We, Le, where W=M×We and L=N ×Le. Here the dimensions of the elementary transistors are We=1µm and Le=1µm, the matrix is of the dimensions 2×3. The elementary transistors Te of a same row are connected in parallel, and those of a same column are connected in series.

It then appears that the periodic variation in the thickness of the TSi thin layer can, depending on the relative positioning of the elementary transistors Te, lead to a degraded matching, whether it is matching between the elementary transistors Te of a same main transistor T, or matching between the main transistors.

Indeed, regarding matching between the elementary transistors Te of a same main transistor T: it appears that, when the elementary transistors adjacent by their sides are close to each other, in the plane XY, given the wavelength λ_{TSi}, the electrical characteristics of each elementary transistor Te can then be modified by the wavelength λ_{TSi}, and matching of the elementary transistors Te of a same main transistor T is degraded.

It is considered here that two elementary transistors adjacent by their sides Te₍ᵢ₎ and Te₍ᵢ₊₁₎ of a same main transistor T are close to each other given λ_{TSi} when the distance d(Te₍ᵢ₎,Te₍ᵢ₊₁₎) is less than or equal to half the wavelength λ_{TSi}/2: d(Te₍ᵢ₎,Te₍ᵢ₊₁₎) ≤ λ_{TSi}/2.

In a general manner, the distance between two elementary transistors is herein defined as being the distance in the plane XY between the geometric center of the gate of the two elementary transistors considered.

Moreover, the elementary transistors have a rectangular shape in the plane XY, thus having four sides and four vertices (or corners). In the remainder of the description, the terms “adjacent by their sides” mean that two elementary transistors are considered whose sides face one another or are opposite one another (hence without the presence of another elementary transistor between them). Furthermore, “adjacent” and “adjacent by their sides” will be used indifferently. If two elementary transistors are adjacent by their vertices are considered, this will then be explicitly set out.

Moreover, with regard to matching between the elementary transistors Te of a same main transistor T: it appears that, when all the elementary transistors T1e of a main transistor T1 are away, in the plane XY, given the wavelength λ_{TSi}, from all the elementary transistors T2e of another main transistor T2, then matching of the main transistors T1 and T2 is degraded.

In other words, when the distance d(C1,C2), in the plane XY, between the centroid C1 of the main transistor T1 and the centroid C2 of the main transistor T2 is greater than the half-wavelength λ_{TSi}/2, then the main transistors T1 and T2 may have a degraded matching.

Indeed, the electrical characteristics of the main transistor T1 may be different from those of the main transistor T2, due to overall variations in the plane XY (temperature gradient, for example).

In order to limit the degradation of matching between the transistors, both with respect to the periodic variation in the thickness of the TSi layer, and with respect to overall variations such as the gradients of parameters (temperature, doping, etc.) during the manufacturing method, there is provided an integrated circuit including an assembly of so-called main FDSOI type field effect transistors, formed in and on a FDSOI substrate. As previously indicated, they each have a channel region located in the TSi thin layer.

The main transistors have dimensions W (width), L (length). According to one embodiment, all the main transistors have the same dimensions W, L.

Each main transistor T is segmented into several elementary transistors Te with dimensions We (width), Le (length), connected together as a matrix of dimensions N×M (N rows and M columns), with W=M×We and L=N×Le. The elementary transistors Te of a same row are connected in parallel, and those of a same column are connected in series. According to one embodiment, all the elementary transistors Te of the main transistors T have the same dimensions We, Le.

The elementary transistors Te of the different main transistors T are aligned in rows and/or columns, so that the elementary transistors are adjacent to their neighbors by their sides facing each other.

The dimensions We, Le of the elementary transistors Te are less than or equal to half the wavelength λ_{TSi}/2: We ≤ λ_{TSi}/2 and Le ≤ λ_{TSi}/2. According to one embodiment, the width We is substantially equal to Le: We = Le. For example, in the case of a wavelength λ_{TSi} equal to about 2.3µm, the dimensions may be We = Le = about 1µm.

In order to limit the degradation of matching associated with the wavelength λ_{TSi} (TSi matching), the elementary transistors Te of a same main transistor T are spaced away from each other, so that two elementary transistors Te₍ᵢ₎ and Te₍ᵢ₊₁₎, successive (along the axis X or Y), are distant by a distance greater than half the wavelength λ_{TSi}/2. If the elementary transistors T1e are considered, there is: d[T1e₍ᵢ₎,T1e₍ᵢ₊₁₎] > λ_{TSi}/2. In other words, the minimum distance between any two elementary transistors of the same main transistor is greater than the half-wavelength λ_{TSi}/2.

Moreover, in order to limit the degradation of matching associated with the overall variations (Pelgrom matching), the elementary transistors, adjacent by their sides (i.e. their sides face each other in the plane XY), belong two by two to different main transistors. In other words, each elementary transistor belongs to a main transistor different from that of the elementary transistor adjacent by their sides. Also, no elementary transistor is adjacent (by one of its sides) to an elementary transistor of the same main transistor.

In addition, the distance, in the plane XY, between two elementary transistors adjacent by their sides, is less than or equal to the half-wavelength λ_{TSi}/2. If the adjacent elementary transistors T1e and T2e are considered, there is: d[T1e,T2e] ≤ λ_{TSi}/2.

On the other hand, the elementary transistors, which are adjacent by their vertices, can belong two by two to identical or different main transistors.

By this relative positioning of the elementary transistors of each main transistor on the one hand, and by that of the elementary transistors of a main transistor with respect to the elementary transistors of the other main transistors, the degradation of matching is limited both with respect to the wavelength λ_{TSi} (TSi matching) and with respect to the overall variations (Pelgrom matching).

It should be noted that these positioning rules apply to any assembly of transistors that should have as identical electrical characteristics as possible, such as, for example, current mirror assemblies as those with differential pairs.

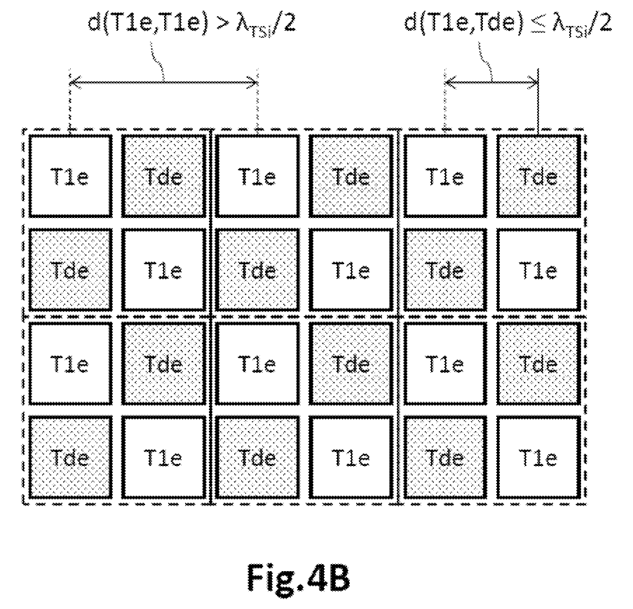

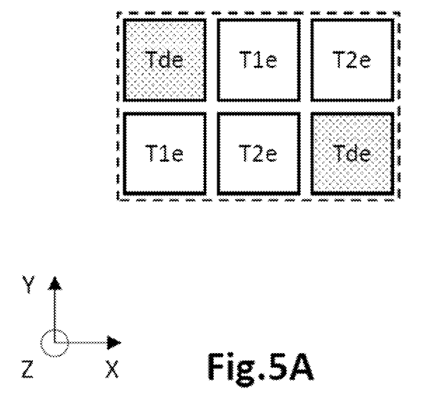

FIG. 3A illustrates an integrated circuit in which matching between the transistors is low, and FIG. 3B illustrates an integrated circuit according to one embodiment, where the assembly of the transistors is equivalent to that of FIG. 3A, but where matching is improved.

In FIG. 3A, the main transistors are connected according to a current mirror assembly, with a diode-assembled main transistor Td and seven main copy transistors T1 to T7. Each main transistor has identical dimensions (W,L), here such as W=3µm and L=1µm.

In this example, the main transistors are not segmented into elementary transistors, nor arranged in an interdigitated manner or with a common centroid. Therefore, their matching is considered to be low and needs to be improved.

In FIG. 3B, each of the main transistors has been segmented into a matrix of 1x3 elementary transistors connected in parallel, each elementary transistor having dimensions (We,Le) less than or equal to the half-wavelength λ_{TSi}/2, with herein: We = Le = 1µm.

The elementary transistors of the different main transistors are aligned in rows and columns. Thus, an elementary transistor has sides that face those of the adjacent elementary transistors.

The elementary transistors of a same main transistor are spaced two by two a distance greater than the half-wavelength λ_{TSi}/2, and here a distance of about 1.5×λ_{TSi} along the axis X. Thus, the different elementary transistors T1e of the main transistor T1 are spaced two by two along the axis X by the distance d(T1e,T1e) equal here to about 1.5×λ _{TSi}. This is also the case for elementary transistors of the main transistors Td, T2, T3, …, T7.

Moreover, each elementary transistor of a same transistor is adjacent by its sides to an elementary transistor of another main transistor. In other words, the elementary transistors are adjacent by their sides and belong two by two to different main transistors. Also, the different elementary transistors T1e are not adjacent to each other (not side-to-side), but are spaced by one or more elementary transistors of other main transistors. Here, the elementary transistors T1e are spaced apart from each other by the elementary transistors T2e and T3e. Similarly, the elementary transistor Tde is not adjacent, by either side thereof, to another elementary transistor Tde.

Finally, the distance, in the plane XY, between two adjacent elementary transistors, is less than or equal to the half-wavelength λ_{TSi}/2. Thus, the elementary transistors T7e and T6e are spaced apart from each other by a distance d(T7e,T6e) ≤ λ_{TSi}/2.

The spacing between the sides facing each other of two adjacent elementary transistors may be in the order of a few hundred nanometers. In this example, this spacing is in the order of 0.15µm, or even less. Also, the distance d(T7e,T6e) is here equal to about 1.15µm, i.e. substantially equal to λ_{TSi}/2.

It therefore appears that the elementary transistors of a same main transistor are decorrelated from each other in terms of wavelength λ_{TSi}, which limits the impact on matching of this periodic variation in the thickness of the TSi layer. Indeed, this arrangement makes it possible to average the effect of the spatial ripple λ_{TSi}, and therefore reduce its impact, on matching of the elementary transistors of a same main transistor. In addition, elementary transistors of a main transistor are correlated with elementary transistors of the other main transistors, which limits the impact on matching of the overall variations as the periodic variation in λ_{TSi}. As a result, matching of the transistors of this current mirror assembly is improved compared to that of FIG. 3A.

Note the presence of dummy transistors Dm, in the unit pattern present three times in the assembly of FIG. 3B, here to the left of the elementary transistors Tde of the diode-assembled main transistor Td. These dummy transistors have the same dimensions (We,Le) as the other elementary transistors and respect the same positioning rules. Here, they make it possible to make the environment “observed” by the neighboring transistors uniform.

The elementary transistors may be arranged so as to form a unit pattern, reproduced as many times as necessary in the plane XY, according to the dimensions and the number of main transistors. The unit pattern is defined so that the transistor assembly complies with the positioning rules set out above.

In general, in order to make an electrical connection of the elementary transistors in good conditions and to limit any parasitic effects, it is preferable that the transistor assembly does not include more than nine main transistors (for example a diode-assembled transistor and 8 copy transistors).

Similarly, it is also preferable that, in each row and each column, the elementary transistors do not belong to more than four main transistors.

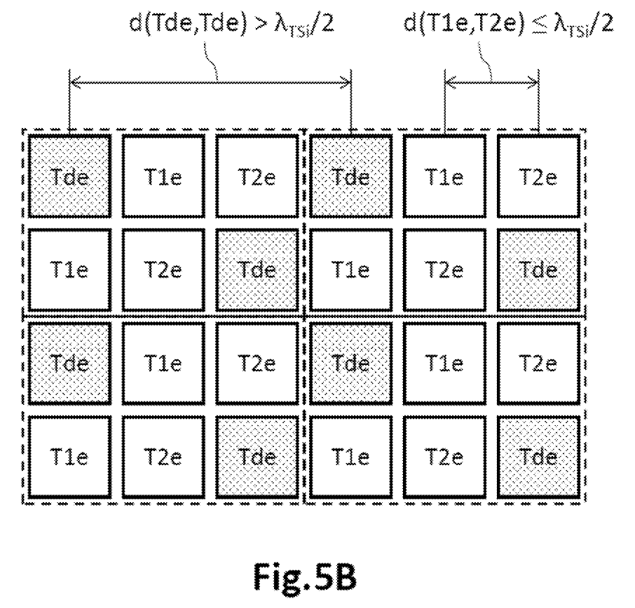

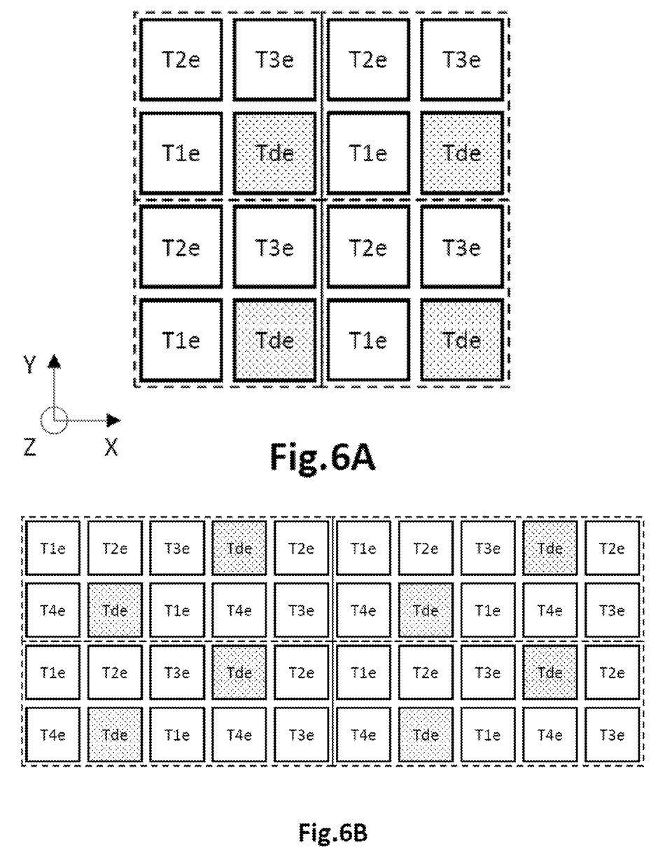

FIG. 4A illustrates an example unit pattern, to be reproduced several times in a transistor assembly of an integrated circuit according to one embodiment.

Here, the unit pattern corresponds to a current mirror formed by a diode-assembled main transistor Td having size W=2, L=1, and a main copy transistor T1 of the same size.

Each main transistor is segmented into two elementary transistors: Tde for the diode-assembled main transistor Td, and T1e for the copy transistor T1.

The elementary transistors are aligned in a matrix of two rows and two columns. To prevent two elementary transistors of a same main transistor from being adjacent to each other by sides facing each other, they are disposed along the diagonal of the matrix of the unit pattern. Thus, elementary transistors T1e are adjacent two to two by their vertices, and they are adjacent two to two by their sides to the elementary transistors Tde.

Each elementary transistor has dimensions (We,Le) less than or equal to half the wavelength λ_{TSi}/2. Here, the width and length are equal to about 1µm: We = Le = 1µm. Each side of an elementary transistor is spaced from the side of the adjacent elementary transistor by a distance herein in the order of about 0.15µm along the axis X and along the axis Y.

FIG. 4B illustrates a transistor assembly including the unit pattern of FIG. 4A, repeated several times in the plane XY, here reproduced three times along the axis X and two times along the axis Y (matrix of two rows and three columns), such that the rows of the unit patterns are parallel to one another from one pattern to another, and the columns are parallel to one another from one pattern to another.

The arrangement of the elementary transistors within the unit pattern makes it possible, when there is a repetition of the unit pattern in the plane XY, to achieve a transistor assembly that complies with the positioning rules mentioned above.

Thus, the elementary transistors of a same transistor are separated from each other by a distance greater than half the wavelength λ_{TSi}/2. Here, two elementary transistors T1e are distant by a distance of the wavelength order λ_{TSi} along the axis X and the axis Y and are diagonally distant by a distance of the order of √2×λ_{TSi}/2. It is reminded that the distance between the elementary transistors is measured from gate center to gate center.

Moreover, each elementary transistor T1e of the transistor T1 is adjacent, on its sides, to the elementary transistors Tde of the transistor Td, and not to another elementary transistor T1e. In addition, the distance between two elementary transistors adjacent by their sides is less than or equal to the half-wavelength λ_{TSi}/2. Thus, the distance here d(T1e,Tde) is here substantially equal to λ_{TSi}/2.

Thus, matching between the transistors is improved, both with regard to the overall variations (Pelgrom matching) and with regard to the periodic variation in the thickness of the TSi layer (TSi matching).

It is noted that, in the case of FIG. 4A, the unit pattern is formed of a diode-assembled main transistor Td and a main copy transistor T1. These main transistors Td, T1 have dimensions (W=2µm; L=1µm) or (W=1µm; L=2µm). Each main transistor is segmented into two elementary transistors, Tde or T1e, with dimensions (We=1µm; Le=1µm).

In the case of FIG. 4B where the unit pattern is reproduced 6 times in a matrix of two rows and three columns, this assembly corresponds to large-size main transistors whose dimensions depend on the routing of the elementary transistors. Thus, multiplying the connections along the axis Y will increase the width W of the main transistor, while multiplying the connections along the axis X will increase the length L. Thus, depending on the routing, each main transistor has one of the following dimensions (here in microns): (W=12 ;L=1) ; (W=6 ;L=2) ; (W=4 ; L=3) ; (W=3 ;L=4) ; (W=2 ;L=6) or (W=1 ;L=12). Generally, as the width W is greater than the length L, each main transistor may have one of the following dimensions: (W=12 ;L=1) ; (W=6 ;L=2) ; or (W=4; L=3).

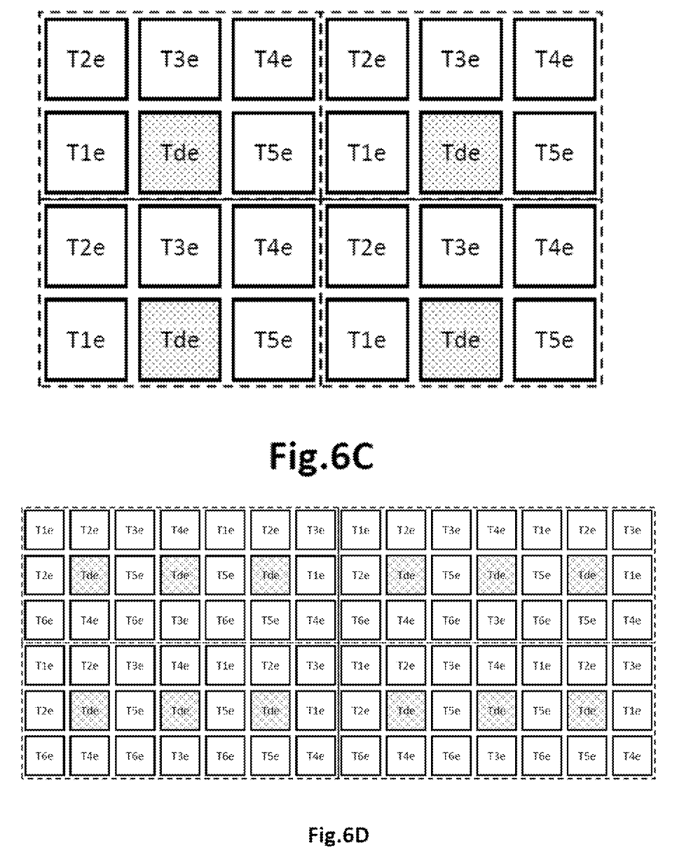

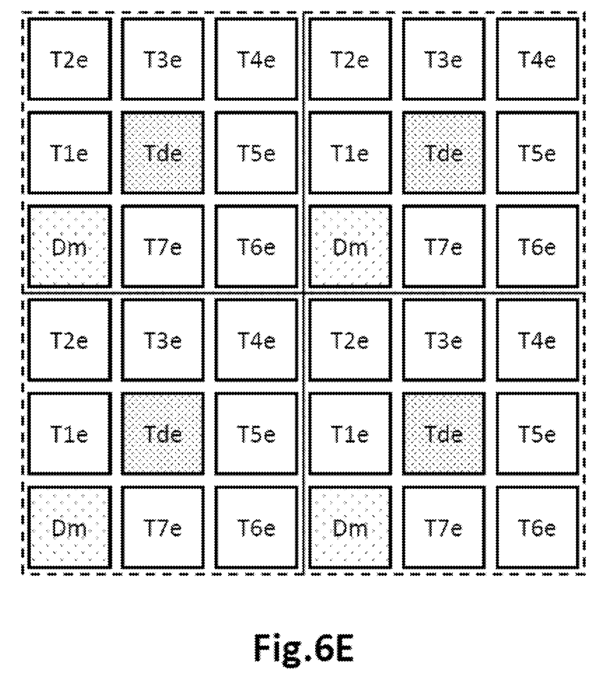

FIG. 5A illustrates another example unit pattern, to be reproduced several times in a transistor assembly of an integrated circuit according to one embodiment.

Here, the unit pattern corresponds to a current mirror formed by a diode-assembled main transistor Td having size W=2, L=1, and two main copy transistors T1 and T2 of the same size.

Each main transistor is segmented into two elementary transistors: Tde for the diode-assembled main transistor Td, and T1e and T2e for the copy transistors T1 and T2. The elementary transistors have a size W=1, L=1, and are spaced two by two (by their opposite sides) by about 0.15µm.

The elementary transistors are aligned in a matrix of two rows and three columns, and are arranged so that the distance between two elementary transistors of a same main transistor is greater than half the wavelength λ_{TSi}/2. As indicated previously, the distance between the elementary transistors is measured from gate center to gate center. Here, the elementary transistors Tde are distant in the order of 1.1×λ_{TSi}, and the elementary transistors T1e are diagonally distant in the order of √2×λ_{TSi}/2 (like the transistors T2e).

Moreover, no elementary transistor is adjacent, by either side thereof, to the other elementary transistor of the same main transistor. This arrangement here allows the unit pattern to be repeated several times in the plane XY.

FIG. 5B illustrates a transistor assembly including the unit pattern of FIG. 5A, reproduced several times in the plane XY, here reproduced twice along the axis X and twice along the axis Y (matrix of two rows and two columns), so that the rows of the unit patterns are parallel to one another from one pattern to another, and the columns are parallel to one another from one pattern to another.

The arrangement of the elementary transistors within the unit pattern makes it possible, when there is a repetition of the unit pattern in the plane XY, to achieve a transistor assembly that complies with the positioning rules mentioned above.

Thus, the elementary transistors of a same transistor are separated from each other by a distance greater than half the wavelength λ_{TSi}/2. Moreover, each elementary transistor of a same main transistor is adjacent, by its sides, to the elementary transistors of other main transistors, and not to the other elementary transistor of the same main transistor. In addition, the distance between two elementary transistors adjacent by their sides is less than or equal to the half-wavelength λ_{TSi}/2.

Thus, matching between the transistors is improved, both with regard to the overall variations (Pelgrom matching) and with regard to the periodic variation in the thickness of the TSi layer (TSi matching).

Moreover, each elementary transistor of a copy transistor is adjacent by one of its faces to an elementary transistor of the diode-assembled transistor, which makes it possible to facilitate routing of the electrical connections.

It is noted that, in the case of FIG. 5A, the unit pattern is formed of a diode-assembled main transistor Td and two main copy transistors T1, T2. These main transistors Td, T1, T2 have dimensions (W=2µm; L=1µm) or (W=1µm; L=2µm). Each main transistor is segmented into two elementary transistors, Tde, T1e, T2e, with dimensions (We=1µm; Le=1µm).

In the case of FIG. 5B where the unit pattern is reproduced four times, in the form of a matrix of two rows and two columns, each main transistor has one of the following dimensions (here in microns): (W=8 ;L=1) ; (W=4 ;L=2) ; (W=2; L=4) ; or (W=1 ;L=8). Since the width W is generally greater than the length L, each main transistor may have one of the following dimensions: (W=8 ;L=1) or (W=4 ;L=2).

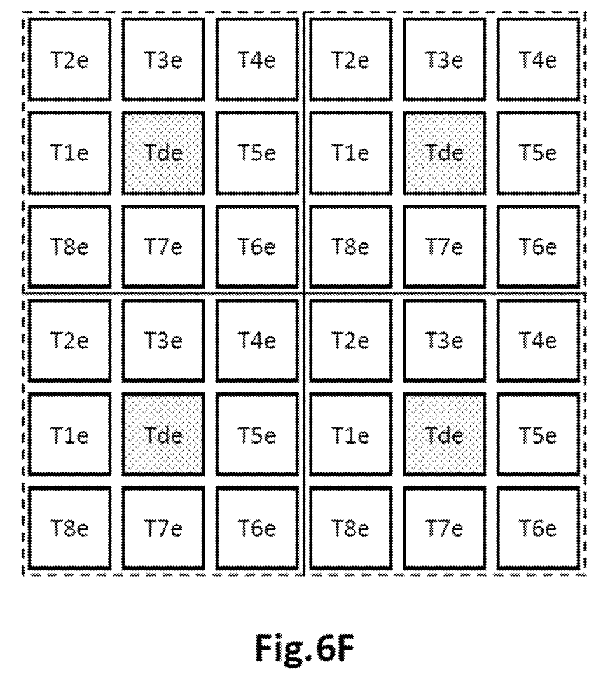

FIGS. 6A to 6F illustrate integrated circuits according to different embodiments, each including a current mirror transistor assembly having three to eight copy transistors, the assembly being formed of a unit pattern of elementary transistors repeated several times in the plane XY, here reproduced twice along the axis X and twice along the axis Y (matrix of two rows and two columns).

As illustrated in FIG. 6A, the unit pattern corresponds to a current mirror formed of a diode-assembled elementary transistor, and of three elementary copy transistors. The elementary transistors here have dimensions (We,Le) less than or equal to the half-wavelength λ_{TSi}/2, with here We = Le = 1µm.

This arrangement of the elementary transistors in this unit makes it possible to comply with the positioning rules mentioned above, both in the unit and when it is repeated in the plane XY: the elementary transistors of a same main transistor are separated from each other by a distance greater than half the wavelength λ_{TSi}/2. Moreover, each elementary transistor of a main transistor is adjacent, by each of its sides, to elementary transistors of other main transistors, and not to another elementary transistor of the same main transistor. Finally, the distance between two elementary transistors adjacent by their sides is less than or equal to the half-wavelength λ_{TSi}/2.

As illustrated in FIG. 6B, the unit pattern corresponds to a current mirror formed of a diode-assembled main transistor Td and four main copy transistors T1 to T4. These main transistors are each segmented into two elementary transistors with dimensions We, Le, here also equal to 1µm.

The elementary transistors are arranged in a matrix of two rows and five columns. On the first row, the elementary transistors are arranged so that there is a succession of T1e, T2e, T3e, Tde, T2e, and on the second row, the succession is, in the same direction as the first row: T4e, Tde, T1e, T4e, T3e. Thus, each elementary copy transistor is adjacent by one of its sides to an elementary transistor of the diode-assembled transistor.

The relative positioning of the elementary transistors in this unit pattern makes it possible to respect the positioning rules mentioned previously, whether in this pattern or in a so-called global matrix where the pattern is repeated in the plane XY. Moreover, it makes it possible to avoid each row and each column of the global matrix not including elementary transistors of more than four different main transistors, thus facilitating routing of the electrical connections.

As illustrated in FIG. 6C, the unit pattern corresponds to a current mirror formed of a diode-assembled elementary transistor Td and of five elementary copy transistors T1 to T5. The transistors are not segmented within the unit pattern insofar as they already have dimensions (We,Le) less than or equal to the half wavelength λ_{TSi}/2, here We = Le = 1µm.

The elementary transistors are arranged in a matrix of two rows and three columns. On the first row, the elementary transistors are arranged so that there is a succession of T2e, T3e, T4e, and on the second row, the succession is, in the same direction as the first row: T1e, Tde, T5e. Thus, each elementary transistor of a copy transistor includes a side or a vertex adjacent, respectively, to a side or a vertex of an elementary transistor of the diode-assembled main transistor.

As previously, this relative positioning of the transistors makes it possible to repeat this pattern several times in a so-called global matrix, while respecting the positioning rules already mentioned.

As illustrated in FIG. 6D, the unit pattern corresponds to a current mirror formed of a diode-assembled main transistor Td and six main copy transistors T1 to T6. The transistors are each segmented into three elementary transistors with dimensions (We,Le) less than or equal to the half-wavelength λ_{TSi}/2, wherein We = Le = 1µm.

The elementary transistors are arranged in a matrix of three rows and seven columns. On the first row, the elementary transistors succeed each other as follows: T1e, T2e, T3e, T4e, T1e, T2e, T3e; on the second row (same direction): T2e, Tde, T5e, Tde, T5e, Tde, T1e; and on the third row (same direction): T6e, T4e, T6e, T3e, T6e, T5e, T4e. Thus, each elementary transistor of a copy transistor includes a side or a vertex adjacent, respectively, to a side or a vertex of an elementary transistor of the diode-assembled main transistor.

As previously, this relative positioning of the transistors makes it possible to repeat this pattern several times in a so-called global matrix, while respecting the positioning rules already mentioned.

As illustrated in FIG. 6E, the unit pattern corresponds to a current mirror formed of a diode-assembled elementary transistor Td and of seven elementary copy transistors T1 to T7, with the presence of a dummy elementary transistor. The transistors are not segmented within the unit pattern insofar as they already have dimensions (We,Le) less than or equal to the half wavelength λ_{TSi}/2, here We = Le = 1µm. The arrangement of the transistors is similar to that of FIG. 3B and is not detailed again.

As illustrated in FIG. 6F, the unit pattern corresponds to a current mirror formed of a diode-assembled elementary transistor Td and eight elementary copy transistors T1 to T8. The arrangement of the transistors is identical to that of FIG. 6E, and differs only in that the elementary transistor T8e is located in place of the dummy elementary transistor. The transistors are not segmented within the unit pattern insofar as they already have dimensions (We,Le) less than or equal to the half wavelength λ_{TSi}/2, here We = Le = 1µm.

It is reminded here that the global matrix which includes the repetition in the plane XY of the unit patterns does not include, on each row and each column, elementary transistors belonging to more than four different main transistors. This makes it easier to route the electrical connections.

In addition, each elementary transistor of a main copy transistor has a side or a corner (vertex) facing, respectively, a side or a corner of an elementary transistor of a diode-assembled main transistor, which makes it possible to facilitate routing of the electrical connections.

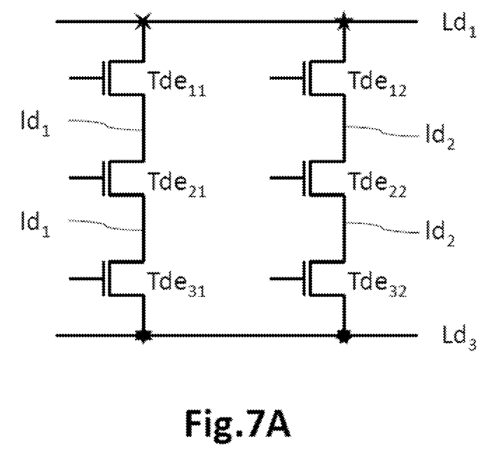

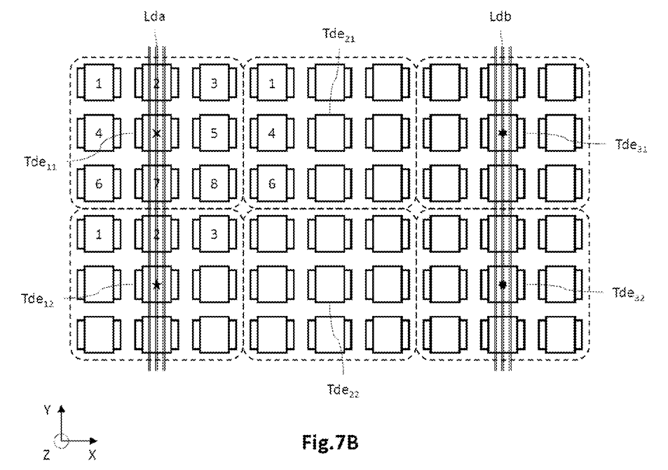

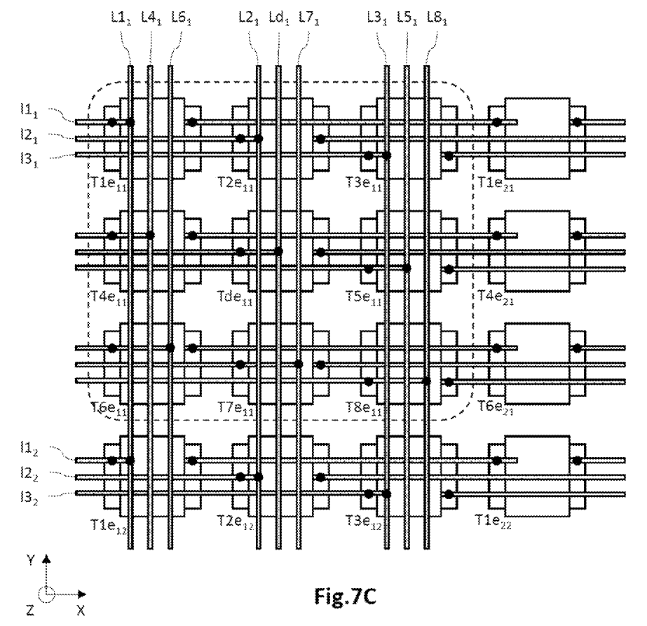

FIG. 7A, FIG. 7B and FIG. 7C illustrate an example of routing of the electrical connections in the case of a current mirror transistor assembly of an integrated circuit according to one embodiment.

The current mirror assembly has nine main transistors: the diode-assembled transistor and 8 copy transistors. Each main transistor has a width equal to 2µm and a length equal to 3µm. Each main transistor is segmented into several elementary transistors with dimensions (We,Le).

FIG. 7A illustrates the segmentation of the diode-assembled main transistor into several elementary transistors Tde. These are arranged in a matrix of three rows and two columns, and have dimensions We = Le = 1µm. The elementary transistors of each column are connected in series and those of each row are connected in parallel.

FIG. 7B illustrates a unit pattern similar to that of FIG. 6F, formed of the elementary transistors of each main transistor: each elementary transistor Tde is surrounded in the plane XY by eight elementary transistors T1e to T8e (noted from 1 to 8). Furthermore, this unit pattern is reproduced six times. It is arranged so as to allow the electrical connection of the elementary transistors according to the segmentation assembly of FIG. 7A.

Thus, conductive lines, here oriented along the axis Y, ensure parallel connection of the elementary transistors. Only part of the conductive lines is represented here. Conductive lines (not represented) oriented along the axis X ensure series connection of the elementary transistors.

Thus, by way of example, the conductive line Lda makes it possible to connect the drain region of the elementary transistors Tde₁₁(see star with 4 branches) and Tde₁₂(see star with 5 branches) while the conductive line Ld_{b} makes it possible to connect the source region of the elementary transistors Tde₃₁ (see star with 6 branches) and Tde₃₂ (see star with 7 branches).

FIG. 7C illustrates in more detail an example of routing the electrical connections of the elementary transistors of a unit pattern of FIG. 7B.

The vertical lines (i.e. oriented along the axis Y) here participate in the parallel connection of the elementary transistors of a same main transistor. Thus, the line L1₁ ensures bias of the drain regions of the transistors T1e₁₁and T1e₁₂, the line L2₁ensures bias of the drain regions of the transistors T2e₁₁and T2e₁₂, and so on.

Moreover, the horizontal lines (i.e. oriented along the axis X) ensure series connection of the elementary transistors of the same main transistor. Thus, the line l1₁ ensures series connection of the transistors T1e₁₁, T1e₂₁ and T1₃₁, line l2₁ ensures series connection of the transistors T2e₁₁, T2e₂₁ and T2e₃₁, and so on. It should be noted that the lines l1₁, l2₁etc. are not continuous metallic connections insofar as they pass through the transistors via their source and drain regions.

Vertical lines and horizontal lines extend in the plane XY but at different heights along the axis Z. The local connection between these lines is ensured by conductive vias represented by solid circles in the figure.

Thus, the arrangement of the elementary transistors in the unit patterns and the repetition thereof makes it possible to improve matching of the transistors while facilitating routing of the electrical connections.

Embodiments have just been described. Various alternatives and modifications will appear to those skilled in the art.

What is claimed is:

1. An integrated circuit, comprising:
a fully depleted semiconductor on insulator (FDSOI) substrate, including a thin top layer of silicon covering an insulating layer, the thin top layer of silicon having a non-zero periodic variation in thickness of a wavelength λ_{TSi};
at least one assembly of main FDSOI-type field effect transistors, formed in and on the FDSOI substrate;
each main transistor segmented into several elementary transistors each having a width We and a length Le both less than or equal to λ_{TSi}/2;
the elementary transistors of a same main transistor being spaced two by two at a first distance greater than λ_{TSi}/2; and
the elementary transistors, adjacent by their sides, belonging two by two to different main transistors, being distant from each other by a second distance less than or equal to λ_{TSi}1/2.

2. The integrated circuit according to claim 1, wherein the wavelength λ_{TSi} is equal to 2.3µm +/- 10%.

3. The integrated circuit according to claim 1, wherein each elementary transistor has the same dimensions for the width We and the length Le.

4. The integrated circuit according to claim 1, wherein the width We and the length Le are equal.

5. The integrated circuit according to claim 1, wherein the width We and the length Le of the elementary transistors are equal to 1µm +/- 10%.

6. The integrated circuit according to claim 1, wherein the elementary transistors are aligned in rows and columns.

7. The integrated circuit according to claim 6, wherein each row and each column includes elementary transistors of at most four different main transistors.

8. The integrated circuit according to claim 1, wherein the at least one assembly of main FDSOI-type field effect transistors consists of, at most, nine main transistors.

9. The integrated circuit according to claim 1, wherein the elementary transistors adjacent by their vertices belong two by two to identical main transistors.

10. The integrated circuit according to claim 1, wherein the elementary transistors adjacent by their vertices belong two by two to different main transistors.

11. The integrated circuit according to claim 1, wherein the elementary transistors are arranged in rows and columns by a repeating unit pattern.

12. The integrated circuit according to claim 11, wherein:
the at least one assembly of main FDSOI-type field effect transistors is a current mirror having a diode-assembled main transistor and at least one main copy transistor; and
the repeating unit pattern includes at least one elementary transistor of the diode-assembled main transistor, and at least one elementary transistor of each main copy transistor.

13. The integrated circuit according to claim 1, wherein:
the at least one assembly of main FDSOI-type field effect transistors is a current mirror having a diode-assembled main transistor and at least one main copy transistor; and
each elementary transistor of a copy transistor includes a first side or first vertex adjacent, respectively, to a second side or second vertex of an elementary transistor of the diode-assembled main transistor.

14. An electronic chip, comprising:
an integrated circuit, comprising:
a fully depleted semiconductor on insulator (FDSOI) substrate, including a thin top layer of silicon covering an insulating layer, the thin top layer of silicon having a non-zero periodic variation in thickness of a wavelength λ_{TSi};
at least one assembly of main FDSOI-type field effect transistors, formed in and on the FDSOI substrate;
each main transistor segmented into several elementary transistors each having a width We and a length Le both less than or equal to λ_{TSi}/2;
the elementary transistors of a same main transistor being spaced two by two at a first distance greater than λ_{TSi}/2; and
the elementary transistors, adjacent by their sides, belonging two by two to different main transistors, being distant from each other by a second distance less than or equal to λ_{TSi}14/2.

15. The electronic chip according to claim 14, wherein:
the wavelength λ_{TSi} is equal to 2.3µm +/- 10%;
each elementary transistor has the same dimensions for the width We and the length Le; or
the width We and the length Le are equal.

16. The electronic chip according to claim 14, wherein the width We and the length Le of the elementary transistors are equal to 1µm +/- 10%.

17. The electronic chip according to claim 14, wherein the elementary transistors are aligned in rows and columns.

18. The electronic chip according to claim 14, wherein the at least one assembly of main FDSOI-type field effect transistors consists of, at most, nine main transistors.

19. The electronic chip according to claim 14, wherein the elementary transistors adjacent by their vertices belong two by two to identical main transistors or different main transistors.

20. The electronic chip according to claim 14, wherein:
the at least one assembly of main FDSOI-type field effect transistors is a current mirror having a diode-assembled main transistor and at least one main copy transistor; and
each elementary transistor of a copy transistor includes a first side or first vertex adjacent, respectively, to a second side or second vertex of an elementary transistor of the diode-assembled main transistor.
